(19) United States
(12) Patent Application Publication
(10) Pub. No.: US 2020/0326134 A1
(43) Pub. Date: Oct. 15, 2020

(54) FLEXIBLE VAPOR CHAMBER

(71) Applicant: AURAS Technology Co., Ltd., New Taipei City (TW)

(72) Inventors: CHIH-WEI CHEN, New Taipei City (TW); CHE-WEI KUO, New Taipei City (TW); TIEN-YAO CHANG, New Taipei City (TW); HSIANG-CHIH CHUANG, New Taipei City (TW)

(21) Appl. No.: 16/823,010

(22) Filed: Mar. 18, 2020

(30) Foreign Application Priority Data
Apr. 12, 2019 (TW) 108112917

(51) Int. Cl. F28D 15/04; F28D 15/02

(52) U.S. Cl. CPC F28D 15/046; H05K 7/20336; F28D 15/0241; F28D 15/0233

(57) ABSTRACT

A flexible vapor chamber for an electronic device includes an upper cover, a lower cover, an accommodation space, a capillary structure, plural support structures and a working fluid. The upper cover is made of a first flexible material. The lower cover is made of a second flexible material. The accommodation space is arranged between the upper cover and the lower cover. The capillary structure is disposed on the lower cover and accommodated within the accommodation space. The plural support structures are disposed on the upper cover and accommodated within the accommodation space. The plural support structures are contacted with the capillary structure. The working fluid is accommodated within the accommodation space. The flexible vapor chamber is permitted to be subjected to a flexural action in a flexible range. Consequently, the installation of the flexible vapor chamber complies with a shape of the electronic device.

### FIELD OF THE INVENTION

The present invention relates to a heat dissipation device, and more particularly to a vapor chamber.

### BACKGROUND OF THE INVENTION

With the increasing development of mobile computing technologies, people have generally used various mobile electronic devices such as notebook computers or smart phones. As the mobile electronic devices are developed toward slimness, the internal spaces of the mobile electronic devices become narrower and narrower. Moreover, as the functions and performance of these mobile electronic devices are gradually enhanced, the electronic components within the mobile electronic devices generate a great deal of heat. If the heat cannot be effectively dissipated away from the narrow internal space, the elevated temperature may result in damage of the electronic components. Consequently, it is an important issue to design the heat dissipation mechanism of the mobile electronic device. The heat sink is contacted and attached to the heat source to absorb heat and conduct heat to the surroundings. Then, the heat is scattered from various positions of the mobile electronic device and released to the air. Consequently, the heat accumulation problem is reduced.

In addition to the heat sink, other type cooling mechanism (e.g., a gas cooling mechanism or a liquid cooling mechanism) is applied to the mobile electronic device. Moreover, a heat pipe is also an effective and common heat dissipation element for the mobile electronic device.

The heat pipe is a hollow metal pipe with two closed ends. A proper amount of working fluid is filled in the chamber of the pipe body. The operation principles of the heat pipe are based on the two-phase change of the working fluid. A heating section is located at a first end of the pipe body. A condensation section is located at a second end of the pipe body. After the working fluid in the heating section absorbs heat from a heat source, the working fluid is transformed from a liquid state into a gaseous state. The heat is diffused within the pipe body and transferred to the condensation section. Then, the heat is exhausted through the heat exchange of an external heat dissipation mechanism.

Moreover, a capillary structure is formed on an inner wall of the pipe body. After the gaseous working fluid releases heat through heat exchange, the gaseous working fluid condenses. Consequently, the working fluid is restored from the gaseous state to the liquid state. Due to the gravity force or the capillary force, the liquid working fluid is returned to the heating section through the capillary structure. By means of the repeated two-phase (liquid/gas) cyclic change, the working fluid is continuously and circularly transferred between the heating section and the condensation section until the both ends tend to be uniform temperature. Consequently, the efficacy of continuously conducting and dissipating heat can be achieved.

However, in case that the internal space of the mobile electronic device is small, the structure of the heat pipe has some drawbacks. For example, in case that the heat pipe has a tubular casing, the heat pipe is usually designed to have the shape corresponding to the mobile electronic device with the heat pipe. After the heat pipe is produced, the shape of the heat pipe is fixed. That is, the shape of the heat pipe is not flexible. Moreover, since the layout space of the heat pipe is small, the diameter of the heat pipe with the tubular casing is not too large.

Nowadays, a vapor chamber (also referred as a heat conduction plate) has been introduced into the market according to the working principles of the heat pipe. The vapor chamber has a wider and flatter plate-form two-dimensional chamber structure. Since the heat conduction area of the vapor chamber is larger than that of the heat pipe and more working fluid is filled in the vapor chamber, the heat dissipation efficacy and the heat conduction capability of the vapor chamber are better. However, since the heat conduction area of the vapor chamber is large, some drawbacks occur. For example, if the structural strength of the casing of the vapor chamber is insufficient, the casing is readily suffered from collapse toward the internal side. Therefore, it is important to increase the structural strength of the vapor chamber while achieving the efficacy of installation flexibility.

### SUMMARY OF THE INVENTION

For solving the drawbacks of the conventional technologies, the present invention provides a flexible vapor chamber for an electronic device. The installation of the flexible vapor chamber complies with a shape of the electronic device. Moreover, the structural strength of the casing is effectively maintained to prevent from the collapse of the internal accommodation space.

In accordance with an aspect of the present invention, a flexible vapor chamber for an electronic device is provided. The flexible vapor chamber includes an upper cover, a lower cover, an accommodation space, a capillary structure, plural support structures and a working fluid. The upper cover is made of a first flexible material. The lower cover is made of a second flexible material. The upper cover is located over the lower cover. The accommodation space is arranged between the upper cover and the lower cover. The capillary structure is disposed on the lower cover and accommodated within the accommodation space. The plural support structures are disposed on the upper cover and accommodated within the accommodation space. The plural support structures are contacted with the capillary structure. The working fluid is accommodated within the accommodation space. The flexible vapor chamber is permitted to be subjected to a flexural action in a flexible range. Consequently, the flexible vapor chamber is installed according to a shape of the electronic device.

In an embodiment, plural trenches are formed in a first outer surface of the upper cover, and two ends of each trench are open ends. When the upper cover is subjected to the flexural action, the plural trenches are shrunken, so that a deformation effect on the first outer surface of the upper cover in response to the flexural action is dispersed.

In an embodiment, plural trenches are formed in a second outer surface of the lower cover, and two ends of each trench are open ends. When the lower cover is subjected to the flexural action, the plural trenches are shrunken, so that a deformation effect on the second outer surface of the lower cover in response to the flexural action is dispersed.

In an embodiment, each of the first flexible material and the second flexible material is copper, copper alloy or aluminum alloy, and the first flexible material and the second flexible material are identical or different.

In an embodiment, the flexible vapor chamber has a specified plate thickness, and the plate thickness is within a predetermined thickness range.

In an embodiment, the flexible vapor chamber further includes an upper film layer and a lower film layer. The upper film layer is located over the upper cover. The lower film layer is located under the lower cover. Moreover, an edge of the upper film layer and an edge of the lower film layer are attached on each other, so that the upper cover and the lower cover are enclosed by the upper film layer and the lower film layer.

In an embodiment, the upper film layer and the lower film layer are made of flexible polymeric materials, and the materials of the upper film layer and the lower film layer are identical or different.

In an embodiment, the lower film layer has an opening, and the lower cover is exposed through the opening. The opening is aligned with a heat source of the electronic device, and the lower cover is in contact with the heat source through the opening.

In an embodiment, the plural support structures are uniformly or non-uniformly distributed on a first inner surface of the upper cover.

In an embodiment, the plural support structures are made of copper, copper alloy or aluminum alloy. The upper cover and the plural support structures are integrally formed as a one-piece structure, or the support structures and the upper cover are individual components and combined together.

In an embodiment, the plural support structures are cylindrical posts, rectangular columns or strip-shaped structures, and a height of each support structure is larger than a thickness of the capillary structure.

In an embodiment, the capillary structure is a copper mesh, or the capillary structure is formed by spreading copper powder over a second inner surface of the lower cover in a sintered or metallurgical manner.

In an embodiment, the flexible vapor chamber further includes an additional capillary structure. The additional capillary structure is disposed on the upper cover, arranged between the plural support structures and accommodated within the accommodation space.

In accordance with another aspect of the present invention, a flexible vapor chamber for an electronic device is provided. The flexible vapor chamber includes an upper cover, a lower cover, an accommodation space, a capillary structure and a working fluid. The upper cover is made of a first flexible material. The lower cover is made of a second flexible material. The upper cover is located over the lower cover. The accommodation space is arranged between the upper cover and the lower cover. The capillary structure is disposed on the lower cover and accommodated within the accommodation space. The capillary structure includes plural protrusion parts. The plural protrusion parts are contacted with the upper cover. The working fluid is accommodated within the accommodation space. The flexible vapor chamber is permitted to be subjected to a flexural action in a flexible range, so that the flexible vapor chamber is installed according to a shape of the electronic device.

In an embodiment, each of the first flexible material and the second flexible material is copper, copper alloy or aluminum alloy, and the first flexible material and the second flexible material are identical or different.

In an embodiment, the flexible vapor chamber has a specified plate thickness, and the plate thickness is within a predetermined thickness range.

In an embodiment, the capillary structure includes plural copper strips, and the plural protrusion parts are formed on the plural copper strips.

From the above descriptions, the flexible vapor chamber includes the support structures to effectively maintain the structural strength of the casing in order to prevent from the collapse of the internal accommodation space. The installation of the flexible vapor chamber complies with a shape of the electronic device. Due to the flexible properties, the installation flexibility of the heat dissipation device is enhanced.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic cross-sectional view illustrating a vapor chamber according to a first embodiment of the present invention and taken along a vertical direction;

FIG. 1B is a schematic cross-sectional view illustrating the vapor chamber according to the first embodiment of the present invention and taken along a horizontal direction;

FIG. 2 schematically illustrates the application of the vapor chamber according to the first embodiment of the present invention;

FIG. 3 is a schematic cross-sectional view illustrating a vapor chamber according to a second embodiment of the present invention and taken along a vertical direction;

FIG. 4 schematically illustrates the application of the vapor chamber according to the second embodiment of the present invention;

FIG. 5 is a schematic cross-sectional view illustrating a vapor chamber according to a third embodiment of the present invention and taken along a vertical direction;

FIG. 6A is a schematic cross-sectional view illustrating a vapor chamber according to a fourth embodiment of the present invention and taken along a vertical direction; and

FIG. 6B is a schematic cross-sectional view illustrating the vapor chamber according to the fourth embodiment of the present invention and taken along a horizontal direction.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the following embodiments and drawings, the elements irrelevant to the concepts of the present invention are omitted and not shown.

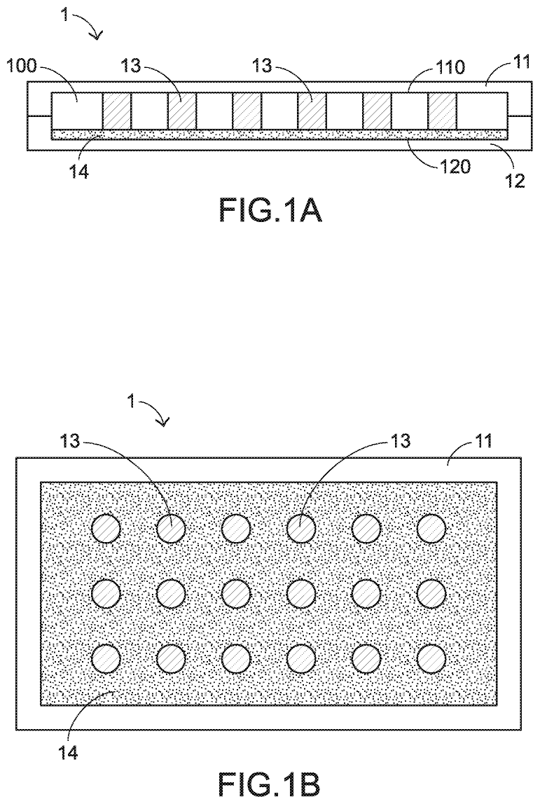

A first embodiment of the present invention will be described as follows. Please refer to FIGS. 1A and 1B. FIG. 1A is a schematic cross-sectional view illustrating a vapor chamber according to a first embodiment of the present invention and taken along a vertical direction. FIG. 1B is a schematic cross-sectional view illustrating the vapor chamber according to the first embodiment of the present invention and taken along a horizontal direction. As shown in FIGS. 1A and 1B, the vapor chamber 1 comprises an upper cover 11, a lower cover 12 and a working fluid (not shown). The upper cover 11 is located over the lower cover 12. An accommodation space 100 is formed between the upper cover 11 and the lower cover 12. After a vacuum state of the accommodation space 100 is created, the working fluid is injected into the accommodation space 100 and then the peripheral region of the accommodation space 100 is sealed. In this embodiment as shown in FIGS. 1A and 1B, the vapor chamber 1 has a rectangular profile. It is noted that the profile of the vapor chamber 1 is not restricted. For example, in another embodiment, the vapor chamber 1 has a square profile.

For example, the working fluid is water, cooling liquid or any other appropriate fluid that has the similar cooling efficacy. The appropriate fluid is methanol, acetone, mercury, or the like. Before the working fluid is heated, the working fluid is in a liquid state. After the working fluid is heated, the working fluid is transformed into a gaseous state through a phase change. After the working fluid is cooled, the working fluid is restored into the liquid state through the phase change. In an operation condition, the working fluid in the accommodation space 100 is in a mixed state of a liquid state and a gaseous state.

In accordance with a feature of the present invention, the vapor chamber 1 is flexible. For acquiring this feature, the upper cover 11 is made of a first flexible material, and the lower cover 12 is made of a second flexible material. When the thermal conduction property of the vapor chamber 1 is taken into consideration, it is preferred that the first flexible material and the second flexible material are metallic materials. For example, each of the first flexible material and the second flexible material is copper, copper alloy or aluminum alloy.

In an embodiment, the first flexible material and the second flexible material are identical. Consequently, the peripheries of the upper cover 11 and the lower cover 12 can be effectively sealed. In some other embodiments, the first flexible material and the second flexible material are different.

In case that the first flexible material and the second flexible material are copper, copper alloy or aluminum alloy and the upper cover 11 and the lower cover 12 are thin (e.g., copper foil), the upper cover 11 and the lower cover 12 have a certain degree of flexible or deformable capability. In other words, the vapor chamber 1 has a specified plate thickness. The plate thickness is within a predetermined thickness range. That is, the specified plate thickness is the overall thickness of the combination of the upper cover 11 and the lower cover 12. For example, the predetermined thickness range is the range between 0.22 and 0.25 millimeters. For assuring the flexible properties of the upper cover 11 and the lower cover 12, the thicknesses of the upper cover 11 and the lower cover 12 are 0.02 mm when the middle segments of the upper cover 11 and the lower cover 12 are not pressed. That is, the height of the accommodation space 100 is about 0.18 to 0.21 mm.

As shown in FIGS. 1A and 1B, the vapor chamber 1 further comprises a capillary structure 14 and plural support structures 13. The capillary structure 14 is disposed on the lower cover 12 and accommodated within the accommodation space 100. The plural support structures 13 are disposed on the upper cover 11 and accommodated within the accommodation space 100. Moreover, the plural support structures 13 are contacted with the capillary structure 14. In an embodiment, the plural support structures 13 are cylindrical posts and uniformly distributed on a first inner surface 110 of the upper cover 11. That is, the plural support structures 13 are discretely arranged on the first inner surface 110 of the upper cover 11 at a specified spacing interval in order to uniformly support the upper cover 11.

It is noted that the arrangements and the shapes of the support structures are not restricted. For example, in another embodiment, the support structures are non-uniformly distributed on a first inner surface 110 of the upper cover 11. For example, since the middle region of the upper cover 11 is able to withstand the larger pressure, a greater number of support structures are disposed in the middle region of the upper cover. Alternatively, the support structures have other shapes. For example, the support structures are rectangular columns or strip-shaped structures.

Moreover, the support structures 13 also have flexible properties. In an embodiment, the support structures 13 are made of the same material as the upper cover 11 (e.g., the metallic material such as copper). In case that the support structures 13 are made of the same material as the upper cover 11, the upper cover 11 and the plural support structures 13 are integrally formed as a one-piece structure. That is, the plural support structures 13 are integrally formed with the upper cover 11 through a metal formation process or any other appropriate means.

In some embodiments, the support structures 13 and the upper cover 11 are made of different materials. For example, the support structures 13 are made of copper, and the first flexible material of the upper cover 11 is copper alloy or aluminum alloy; or the support structures 13 are made of copper alloy or aluminum alloy, and the first flexible material of the upper cover 11 is copper. That is, the upper cover 11 and the support structures 13 are different components. After the support structures 13 and the upper cover 11 are produced individually, the support structures 13 and the upper cover 11 are combined together through a metal formation process or any other appropriate means.

Since the associated components are small, the manufacturing process of the vapor chamber 1 is specially designed. Firstly, the upper cover 11 and the lower cover 12 are produced. Then, the plural support structures 13 are disposed on the first inner surface 110 of the upper cover 11, and the capillary structure 14 is disposed on a second inner surface 120 of the lower cover 12. Then, the upper cover 11 and the lower cover 12 are combined together along the vertical direction through a sintering process, a hot welding process, a laminating process or any other appropriate bonding process. Consequently, the plural support structures 13 and the capillary structure 14 accommodated within the accommodation space 100 are contacted with each other. That is, the capillary structure 14 is pressed by the plural support structures 13. Moreover, during the manufacturing process of the vapor chamber 1, the heating process may facilitate the connection between the support structures 13 and the capillary structure 14. In such way, the support structures 13 and the capillary structure 14 will not be detached because of the flexural action, the deformation or the high temperature environment.

In an embodiment, the capillary structure 14 is a copper mesh, and the copper mesh is spread over the second inner surface 120 of the lower cover 12. It is noted that the method of forming the capillary structure 14 is not restricted. For example, the capillary structure 14 is formed by spreading copper powder over the second inner surface 120 of the lower cover 12 in a sintered or metallurgical manner.

The thickness of the capillary structure 14 is small. For effectively supporting the upper cover 11 to result in a larger airflow channel in the accommodation space 100, the height of each support structure 13 is larger than the thickness of the capillary structure 14. For example, in case that the overall thickness of the combination of the upper cover 11 and the lower cover 12 is in the range between 0.22 and 0.25 mm, the height of each support structure 13 is in the range between 0.12 and 0.14 mm and the thickness of the capillary structure 14 is in the range between 0.06 and 0.07 mm. In other words, the height of the airflow channel defined by the plural support structures 13 is at least 0.12 mm.

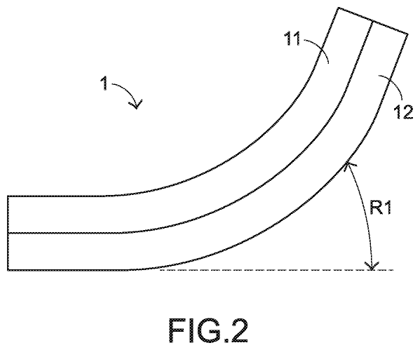

FIG. 2 schematically illustrates the application of the vapor chamber according to the first embodiment of the present invention. In response to the flexural action of the vapor chamber 1, the vapor chamber 1 is subjected to deformation. In accordance with a design, the associated components have the flexible properties, and the plural support structures 13 and the capillary structure 14 are not suffered from excess dislocation. Consequently, the flexural action of the overall vapor chamber 1 is limited to a flexible range R1. In FIG. 2, the flexible range R1 is along the two-dimensional plane. It is noted that the flexural action of the vapor chamber 1 may be applied along any direction in the space.

The vapor chamber 1 may be applied to an electronic device (not shown). For example, the electronic device is a notebook computer, a flexible mobile phone or a flip-type mobile phone. After the vapor chamber 1 is subjected to the flexural action to comply with the electronic device, the vapor chamber can be attached on the electronic device according to the profile of the electronic device.

In an example, the display screen and the keyboard of the notebook computer are rotatable relative to each other. A first portion of the vapor chamber 1 is attached on a heat source of the main body of the keyboard. A second portion of the vapor chamber 1 is extended to and installed on the display screen. Consequently, the heat of the notebook computer can be dissipated to the surroundings more easily. In another example, the vapor chamber 1 is installed in the mobile phone, and the entire of the mobile phone has the flexible or bendable capacity. The vapor chamber 1 of the present invention is suitably used as the heat dissipation mechanism of this type of electronic device. That is, the vapor chamber 1 is installed in the main body of the electronic device according to the bending degree of the electronic device. Similarly, the vapor chamber 1 can be applied to the flip-type mobile phone. The installation of the vapor chamber 1 in the flip-type mobile phone is similar to the installation in the notebook computer.

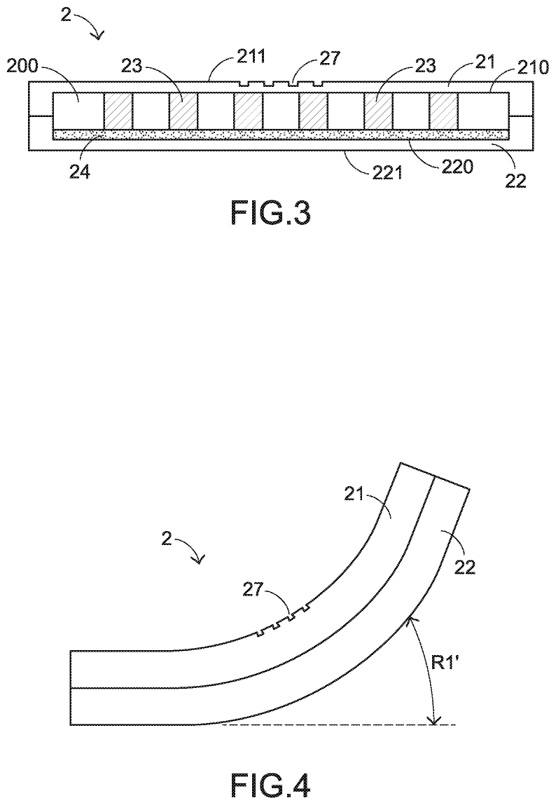

A second embodiment of the present invention will be described as follows. Please refer to FIGS. 3 and 4. FIG. 3 is a schematic cross-sectional view illustrating a vapor chamber according to a second embodiment of the present invention and taken along a vertical direction. FIG. 4 schematically illustrates the application of the vapor chamber according to the second embodiment of the present invention. Component parts and elements corresponding to those of the first embodiment are designated by similar numeral references. In this embodiment, the vapor chamber 2 comprises an upper cover 21, a lower cover 22, an accommodation space 200, a capillary structure 24, plural support structures 23, a first inner surface 210 and a second inner surface 220. In comparison with the first embodiment, plural trenches 27 are formed in a first outer surface 211 of the upper cover 21. The two ends of each trench 27 are open ends. When the upper cover 21 is subjected to the flexural action, the plural trenches 27 are shrunken. Consequently, the deformation effect on the first outer surface 211 of the upper cover 21 in response to the flexural action will be dispersed.

In addition to the flexible properties, the upper cover 21 and the lower cover 22 have ductility and compressibility. However, the extrusion between the components (or materials) may influence the effect of the flexural action. The arrangement of the plural trenches 27 can reduce the local thickness of the upper cover 21. Moreover, the plural trenches 27 run through a portion of the first outer surface 211 of the upper cover 21 along the horizontal direction. Since the orientation of the plural trenches 27 substantially coincides with the axial center of the region undergoing the flexural action, the plural trenches 27 provide the buffering space for the compressive deformation while the flexural action is subjected.

Preferably, the region of the lower cover 22 under the plural trenches 27 is not aligned with the heat source (not shown). That is, the region of the lower cover 22 under the plural trenches 27 is separated from the heat source. Since the region of the lower cover 22 under the plural trenches 27 in response to the flexural action has the larger deformation amount, it is preferred that the region of the lower cover 22 under the plural trenches 27 is not contacted with the heat source. The region of the lower cover 22 contacting with the heat source has the lower deformation amount or no deformation amount. Consequently, the lower cover 22 can be in close contact with the heat source to transfer the heat.

In this embodiment, the plural trenches 27 are formed in the first outer surface 211 of the upper cover 21 according to the inward flexural action of the upper cover 21 in the flexible range R1′. It is noted that numerous modifications and alterations may be made while retaining the teachings of the invention. For example, in another embodiment, the trenches are formed in a second outer surface 221 of the lower cover 22 according to the inward flexural action of the lower cover 22. Consequently, the deformation effect on the second outer surface 221 of the lower cover 22 in response to the flexural action will be dispersed. Alternatively, plural trenches are formed in the first outer surface 211 of the upper cover 21 and the second outer surface 221 of the lower cover 22 according to the inward flexural action of the upper cover 21 and the inward flexural action of the lower cover 22.

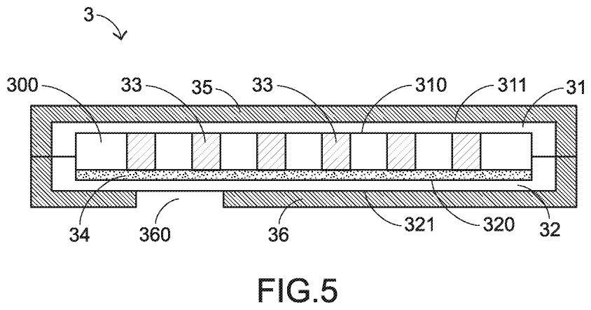

A third embodiment of the present invention will be described as follows. Please refer to FIG. 5. FIG. 5 is a schematic cross-sectional view illustrating a vapor chamber according to a third embodiment of the present invention and taken along a vertical direction. Component parts and elements corresponding to those of the first embodiment are designated by similar numeral references. In this embodiment, the vapor chamber 3 comprises an upper cover 31, a lower cover 32, an accommodation space 300, a capillary structure 34, plural support structures 33, a first inner surface 310 and a second inner surface 320. In comparison with the first embodiment, the vapor chamber 3 of this embodiment further comprises an upper film layer 35 and a lower film layer 36.

The upper film layer 35 is disposed on a first outer surface 311 of the upper cover 31. The lower film layer 36 is disposed on a second outer surface 321 of the lower cover 32. That is, the upper film layer 35 is located over the upper cover 31, and the lower film layer 36 is located under the lower cover 32. Moreover, the edges of the upper film layer 35 and the edges of the lower film layer 36 are attached on each other, and thus the upper cover 31 and the lower cover 32 are enclosed by the upper film layer 35 and the lower film layer 36.

In an embodiment, the upper film layer 35 and the lower film layer 36 are made of flexible polymeric materials such as plastic materials or rubber resins. Although the heat conduction properties of the upper film layer 35 and the lower film layer 36 are not good, the upper film layer 35 and the lower film layer 36 have good flexible properties and provide protective efficacy like the cable sheathes. In such way, the upper film layer 35 and the upper cover 31 are formed as an upper composite structure, and the lower film layer 36 and the lower cover 32 are formed as a lower composite structure.

For example, each of the upper composite structure and the lower composite structure comprises a plastic layer and a metal layer. A process of manufacturing the composite structure will be described as follows. Firstly, the edges of the metal layer are removed by an etching technology, and thus a portion of the external plastic layer is exposed. The exposed portion of the external plastic layer is the region to be subjected to the hot press process or the glue coating process. For effectively bonding the edges of the upper film layer 35 and the edges of the lower film layer 36 together, the upper film layer 35 and the lower film layer 36 are made of the same material. In some other embodiments, the upper film layer 35 and the lower film layer 36 are made of different materials.

Please refer to FIG. 5 again. In this embodiment, the lower film layer 36 is not in thermal contact with the heat source. The lower film layer 36 has an opening 360. The lower cover 32 is exposed through the opening 360. The opening 360 is aligned with the heat source (e.g., a central processing unit) of an electronic device. Consequently, the lower cover 32 can be in contact with the heat source to transfer heat.

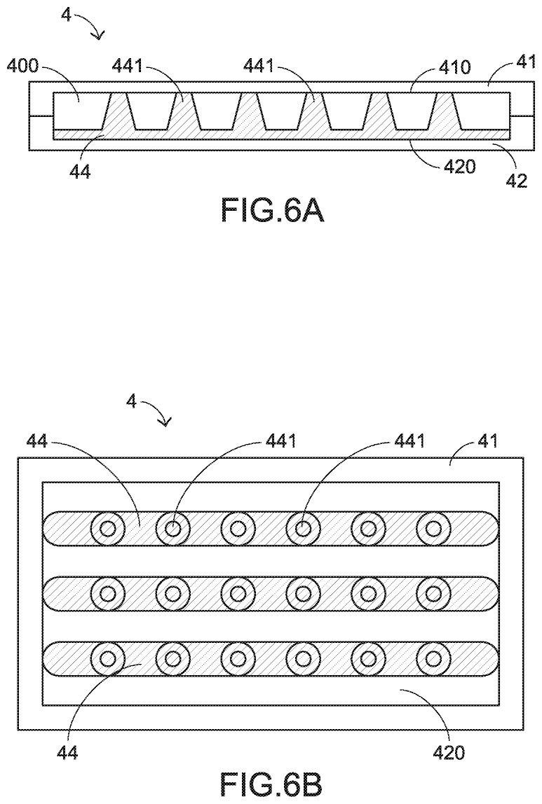

A fourth embodiment of the present invention will be described as follows. Please refer to FIGS. 6A and 6B. FIG. 6A is a schematic cross-sectional view illustrating a vapor chamber according to a fourth embodiment of the present invention and taken along a vertical direction. FIG. 6B is a schematic cross-sectional view illustrating the vapor chamber according to the fourth embodiment of the present invention and taken along a horizontal direction. Component parts and elements corresponding to those of the first embodiment are designated by similar numeral references. In this embodiment, the vapor chamber 4 comprises an upper cover 41, a lower cover 42, an accommodation space 400, a capillary structure 44, a first inner surface 410 and a second inner surface 420. In comparison with the first embodiment, the vapor chamber 4 of this embodiment is not equipped with the support structures on the upper cover 41.

In this embodiment, the capillary structure 44 comprises plural protrusion parts 441. Each of the plural protrusion parts 441 has a specified height. The plural protrusion parts 441 are contacted with the upper cover 41 to provide the supporting functions similar to the support structures of the above embodiments. In other words, the capillary structure 44 not only provide the capillary function of centralizing the working fluid but also provide the supporting function of preventing the collapse of the upper cover 41.

For achieving the supporting function, the capillary structure 44 comprises plural copper strips, and the plural protrusion parts 441 are formed on the plural copper strips. In an embodiment, each copper strip is produced by braiding plural thin copper lines and has a shape of a “shoelace”. When the braided copper strip reaches a specified thickness or portions of the braided copper strip are protruded, the protruded portions of the braided copper strip are served as the protrusion parts 441. Then, the plural copper strips are placed on the second inner surface 420 of the lower cover 42 successively and centralized. Consequently, the capillary structure 44 with the efficacy of a copper mesh is produced. In addition, the plural protrusion parts 441 provide the supporting functions similar to the plural support structures of the above embodiments.

It is noted that numerous modifications and alterations may be made while retaining the teachings of the invention.

In the above embodiments, the capillary structure is disposed on the lower cover. Alternatively, the vapor chamber further comprises an additional capillary structure. The additional capillary structure is disposed on the upper cover, arranged between the plural support structures and accommodated within the accommodation space. Since the support structures are disposed on the inner surface of the upper cover, the support structures are penetrated through the additional capillary structure. Alternatively, the additional capillary structure comprises plural copper strips, which are produced by the method as described in the fourth embodiment. Consequently, the plural copper strips are placed on the first inner surface of the upper cover successively and centralized to avoid the difficulty of disposing the entire of the copper mesh.

Alternatively, the capillary structure with the capillary function and the supporting function can be produced by a 3D printing technology or any other appropriate method. Moreover, the capillary structure with the capillary function and the supporting function is made of a metallic material. Preferably but not exclusively, the metallic material is copper. Moreover, the component of the capillary structure is not limited to the strip-shape structure or the above “shoelace-shaped” structure. For example, the component of the capillary structure has a shape of “pen holder”, a shape of a “paperweight”, a shape of a slice or a shape of a flat sheet. In other words, since the capillary structure has the capillary function and the supporting function, the protrusion parts of the capillary structure providing the supporting function have capillary pores.

From the above descriptions, the flexible vapor chamber of the present invention provides a large area to transfer heat quickly, effectively maintains the structural strength of the casing to prevent from the collapse of the internal accommodation space. Due to the flexible properties, the installation flexibility of the heat dissipation device is enhanced. Consequently, the vapor chamber is suitably used in specified electronic devices.

In other words, the technologies of the present invention can overcome the drawbacks of the conventional technologies while achieving the objects of the present invention.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A flexible vapor chamber for an electronic device, the flexible vapor chamber comprising:
an upper cover made of a first flexible material;
an lower cover made of a second flexible material, wherein the upper cover is located over the lower cover;
an accommodation space arranged between the upper cover and the lower cover;
a capillary structure disposed on the lower cover and accommodated within the accommodation space;
plural support structures disposed on the upper cover and accommodated within the accommodation space, wherein the plural support structures are contacted with the capillary structure; and
a working fluid accommodated within the accommodation space,
wherein the flexible vapor chamber is permitted to be subjected to a flexural action in a flexible range, so that the flexible vapor chamber is installed according to a shape of the electronic device.

2. The flexible vapor chamber according to claim 1, wherein plural trenches are formed in a first outer surface of the upper cover, and two ends of each trench are open ends, wherein when the upper cover is subjected to the flexural action, the plural trenches are shrunken, so that a deformation effect on the first outer surface of the upper cover in response to the flexural action is dispersed.

3. The flexible vapor chamber according to claim 1, wherein plural trenches are formed in a second outer surface of the lower cover, and two ends of each trench are open ends, wherein when the lower cover is subjected to the flexural action, the plural trenches are shrunken, so that a deformation effect on the second outer surface of the lower cover in response to the flexural action is dispersed.

4. The flexible vapor chamber according to claim 1, wherein each of the first flexible material and the second flexible material is copper, copper alloy or aluminum alloy, and the first flexible material and the second flexible material are identical or different.

5. The flexible vapor chamber according to claim 1, wherein the flexible vapor chamber has a specified plate thickness, and the plate thickness is within a predetermined thickness range.

6. The flexible vapor chamber according to claim 1, further comprising:
an upper film layer located over the upper cover; and
a lower film layer located under the lower cover,
wherein an edge of the upper film layer and an edge of the lower film layer are attached on each other, so that the upper cover and the lower cover are enclosed by the upper film layer and the lower film layer.

7. The flexible vapor chamber according to claim 6, wherein the upper film layer and the lower film layer are made of flexible polymeric materials, and the materials of the upper film layer and the lower film layer are identical or different.

8. The flexible vapor chamber according to claim 6, wherein the lower film layer has an opening, and the lower cover is exposed through the opening, wherein the opening is aligned with a heat source of the electronic device, and the lower cover is in contact with the heat source through the opening.

9. The flexible vapor chamber according to claim 1, wherein the plural support structures are uniformly or non-uniformly distributed on a first inner surface of the upper cover.

10. The flexible vapor chamber according to claim 1, wherein the plural support structures are made of copper, copper alloy or aluminum alloy, wherein the upper cover and the plural support structures are integrally formed as a one-piece structure, or the support structures and the upper cover are individual components and combined together.

11. The flexible vapor chamber according to claim 1, wherein the plural support structures are cylindrical posts, rectangular columns or strip-shaped structures, and a height of each support structure is larger than a thickness of the capillary structure.

12. The flexible vapor chamber according to claim 1, wherein the capillary structure is a copper mesh, or the capillary structure is formed by spreading copper powder over a second inner surface of the lower cover in a sintered or metallurgical manner.

13. The flexible vapor chamber according to claim 1, further comprising an additional capillary structure, wherein the additional capillary structure is disposed on the upper cover, arranged between the plural support structures and accommodated within the accommodation space.

14. A flexible vapor chamber for an electronic device, the flexible vapor chamber comprising:
an upper cover made of a first flexible material;
an lower cover made of a second flexible material, wherein the upper cover is located over the lower cover;
an accommodation space arranged between the upper cover and the lower cover;
a capillary structure disposed on the lower cover and accommodated within the accommodation space, wherein the capillary structure comprises plural protrusion parts, and the plural protrusion parts are contacted with the upper cover; and
a working fluid accommodated within the accommodation space,
wherein the flexible vapor chamber is permitted to be subjected to a flexural action in a flexible range, so that the flexible vapor chamber is installed according to a shape of the electronic device.

15. The flexible vapor chamber according to claim 14, wherein each of the first flexible material and the second flexible material is copper, copper alloy or aluminum alloy, and the first flexible material and the second flexible material are identical or different.

16. The flexible vapor chamber according to claim 14, wherein the flexible vapor chamber has a specified plate thickness, and the plate thickness is within a predetermined thickness range.

17. The flexible vapor chamber according to claim 14, wherein the capillary structure comprises plural copper strips, and the plural protrusion parts are formed on the plural copper strips.
